(19) United States
(12) Patent Application Publication
(10) Pub. No.: US 2025/0021121 A1
(43) Pub. Date: Jan. 16, 2025

(54) Voltage Regulator with Voltage Rail Switching

(71) Applicant: Apple Inc., Cupertino, CA (US)

(72) Inventors: Adrien Vargas, Munich (DE); Jerome Casters, Munich (DE); Guillaume Gourlat, Weilheim (DE); Timo W. Gossmann, Neubiberg (DE); Mina Mofreh Gad Elsayed Abdallah, Munich (DE)

(21) Appl. No.: 18/349,792

(22) Filed: Jul. 10, 2023

(51) Int. Cl. G05F 1/575; H03K 17/687; H03K 19/173; H04B 1/40

(52) U.S. Cl. CPC G05F 1/575; H03K 17/687; H03K 19/173; H04B 1/40

(57) ABSTRACT

Voltage regulator circuitry is provided that includes a pass transistor, an error amplifier for regulating the pass transistor, a high rail switch coupled between a first power supply line and the pass transistor, a big low rail switch coupled between a second power supply line and the pass transistor, a small low rail switch coupled between the second power supply line and the pass transistor, and a comparator for monitor a current flowing through or a voltage across the small low rail switch. The small low rail switch, the comparator, and a gating logic can be coupled in an analog feedback loop. The voltage regulator circuitry can include a sequencer for controlling the high rail switch, the big low rail switch, and the gating logic to perform fast seamless transitions between a low voltage rail mode and a high voltage rail mode without incurring large current glitches.

### FIELD

This disclosure relates generally to electronic devices and, more particularly, to electronic devices with wireless communications circuitry.

### BACKGROUND

Electronic devices are often provided with wireless communications capabilities. An electronic device with wireless communications capabilities has wireless communications circuitry with one or more antennas. The wireless communications circuitry uses the antennas to receive radio-frequency signals and to transmit radio-frequency signals.

Signals transmitted by the antennas are fed through a transceiver to a front end module. Circuits within the front end module can receive a regulated voltage from a voltage regulator. It can be challenging to design a satisfactory voltage regulator for the wireless communications circuitry.

### SUMMARY

An electronic device may include wireless communications circuitry. The wireless communications circuitry may include one or more processors configured to output baseband signals to a transceiver, a radio-frequency front end module for receiving signals from the transceiver, and an antenna coupled to the radio-frequency front end module and configured to transmit radio-frequency signals. The wireless communications circuitry and other circuits within the electronic device can receive one or more regulated voltage from voltage regulator circuitry.

An aspect of the disclosure provides voltage regulator circuitry that includes a pass transistor having a source terminal coupled to an output port of the voltage regulator circuitry on which a regulated voltage is provided, an amplifier having a first input configured to receive a reference voltage, a second input coupled to the source terminal of the pass transistor, and an output coupled to a gate terminal of the pass transistor, a first switch coupled between a first power supply line and a drain terminal of the pass transistor, and a second switch coupled between the first power supply line and the drain terminal of the pass transistor. The voltage regulator circuitry can further include a third switch coupled between a second power supply line different than the first power supply line and the drain terminal of the pass transistor. A first power supply voltage can be provided on the first power supply line. A second power supply voltage can be provided on the second power supply line. The first power supply voltage can be greater than the second power supply voltage. The voltage regulator circuitry can further include a comparator having input terminals coupled across the first switch and configured to generate a comparator output signal, a gating circuit configured to receive the comparator output signal and to output a first control signal for controlling the first switch, and a control circuit configured to output a first arming signal and a second arming signal to the gating circuit, to output a second control signal for controlling the first switch, and to output a third control signal for controlling the second switch. The second switch can be at least two times larger than the first switch.

An aspect of the disclosure provides a method of operating voltage regulator circuitry that includes: outputting, by an error amplifier, a control signal to a pass transistor; deactivating a second low rail switch coupled between a first power supply line and the pass transistor; after deactivating the second low rail switch, activating a high rail switch coupled between a second power supply line different than the first power supply line and the pass transistor; and receiving, at a comparator, a voltage across a first low rail switch coupled between the first power supply line and the pass transistor. The method can further include asserting an arming signal to arm the comparator after deactivating the second low rail switch and before activating the high rail switch. The method can further include toggling a comparator output signal at an output of the comparator in response to a voltage across the first low rail switch exceeding a threshold of the comparator. The method can further include deactivating the first low rail switch in response to the comparator output signal toggling.

An aspect of the disclosure provides a method of operating voltage regulator circuitry that includes: outputting, by an error amplifier, a control signal to a pass transistor; deactivating a high rail switch coupled between a first power supply line and the pass transistor; receiving, at a comparator, a voltage across a first low rail switch coupled between a second power supply line different than the first power supply line and the pass transistor; and in response to the voltage across the first low rail switch exceeding a threshold of the comparator, toggling a comparator output signal at an output of the comparator. The method can further include asserting an arming signal to arm the comparator before deactivating the high rail switch. The method can further include activating the first low rail switch in response to the comparator output signal toggling. The method can further include activating a second low rail switch that is coupled between the second power supply line and the pass transistor after activating the first low rail switch.

### BRIEF DESCRIPTION OF THE DRAWINGS

FIG. 1 is a diagram of an illustrative electronic device having wireless communications circuitry in accordance with some embodiments.

FIG. 2 is a diagram of illustrative wireless communications circuitry configured to receive a regulated voltage from a voltage regulator in accordance with some embodiments.

FIG. 3 is a circuit diagram of illustrative voltage regulator circuitry in accordance with some embodiments.

FIG. 4 is a timing diagram illustrating a low voltage rail to high voltage rail transition in accordance with some embodiments.

FIG. 5 is a timing diagram illustrating a high voltage rail to low voltage rail transition in accordance with some embodiments.

FIG. 6 is a circuit diagram of an illustrative comparator with hysteresis in accordance with some embodiments.

FIG. 7 is a circuit diagram of an illustrative gating logic circuit in accordance with some embodiments.

FIG. 8 is a flow chart of illustrative steps for operating voltage regulator circuitry of the type shown in FIGS. 2-7 in accordance with some embodiments.

### DETAILED DESCRIPTION

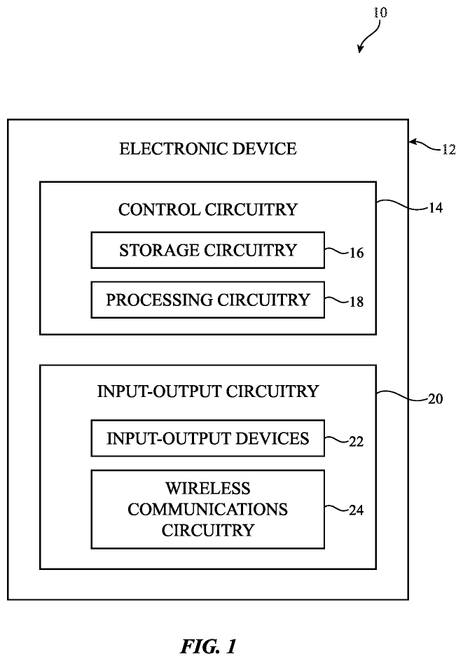

An electronic device such as electronic device 10 of FIG. 1 may be provided with wireless circuitry. The wireless circuitry may include a voltage regulator configured to provide a regulated voltage to one or more load circuits within the wireless circuitry. The voltage regulator may be a voltage regulator such as a low dropout (LDO) voltage regulator operable in (1) a low voltage rail mode to generate a low regulated voltage and (2) a high voltage rail mode to generate a high regulated voltage. The voltage regulator may include a main switch having a drain terminal coupled to a high rail switch A, a big low rail switch B, and a small low rail switch C. The high rail switch A can be coupled between the drain terminal of the main switch and a high voltage rail VDD_A. The big low rail switch B can be coupled between the drain terminal of the main switch and a low voltage rail VDD_B. The small low rail switch C can be coupled between the drain terminal of the main switch and the low voltage rail VDD_B.

The switches A, B, and C can be controlled by a state machine. A comparator can have inputs coupled across the source and drain terminals of the small low rail switch C and can have an output coupled to a gating logic. The gating logic can receive arming signals from the state machine and can selectively pass the comparator output to the gate of the small low rail switch C. During a low rail to high rail mode transition, the state machine first disables the big low rail switch B, then arms the gating logic, and enables the high rail switch A. The gating logic then disables the remaining small low rail switch C when the comparator sees detects cross-current flowing through the small low rail switch C. During a high rail to low rail mode transition, the state machine first arms the gating logic and then turns off the high rail switch A (which then allows the voltage at the drain terminal of the main switch to start dropping since no switch is actively connected to the supply). The gating logic then enables the small low rail switch C when the comparator detects an unwanted voltage drop across the small low rail switch C, and then later activates the big low rail switch B.

Voltage regulator circuitry configured and operated in this way can be technically advantageous and beneficial by enabling fast seamless transitions between the high voltage rail mode and the low voltage rail mode while limiting transient current glitches and unwanted voltage drops. As an example, transitioning between the high and low rail modes can occur within 500 nanoseconds or less.

Electronic device 10 of FIG. 1 may be a computing device such as a laptop computer, a desktop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses or other equipment worn on a user's head, or other wearable or miniature device, a television, a computer display that does not contain an embedded computer, a gaming device, a navigation device, an embedded system such as a system in which electronic equipment with a display is mounted in a kiosk or automobile, a wireless internet-connected voice-controlled speaker, a home entertainment device, a remote control device, a gaming controller, a peripheral user input device, a wireless base station or access point, equipment that implements the functionality of two or more of these devices, or other electronic equipment.

As shown in the schematic diagram FIG. 1, device 10 may include components located on or within an electronic device housing such as housing 12. Housing 12, which may sometimes be referred to as a case, may be formed of plastic, glass, ceramics, fiber composites, metal (e.g., stainless steel, aluminum, metal alloys, etc.), other suitable materials, or a combination of these materials. In some situations, parts or all of housing 12 may be formed from dielectric or other low-conductivity material (e.g., glass, ceramic, plastic, sapphire, etc.). In other situations, housing 12 or at least some of the structures that make up housing 12 may be formed from metal elements.

Device 10 may include control circuitry 14. Control circuitry 14 may include storage such as storage circuitry 16. Storage circuitry 16 may include hard disk drive storage, nonvolatile memory (e.g., flash memory or other electrically-programmable-read-only memory configured to form a solid-state drive), volatile memory (e.g., static or dynamic random-access-memory), etc. Storage circuitry 16 may include storage that is integrated within device 10 and/or removable storage media.

Control circuitry 14 may include processing circuitry such as processing circuitry 18. Processing circuitry 18 may be used to control the operation of device 10. Processing circuitry 18 may include on one or more microprocessors, microcontrollers, digital signal processors, host processors, baseband processor integrated circuits, application specific integrated circuits, central processing units (CPUs), graphics processing units (GPUs), neural processing units (NPUs), power management units (PMUs), etc. Control circuitry 14 may be configured to perform operations in device 10 using hardware (e.g., dedicated hardware or circuitry), firmware, and/or software. Software code for performing operations in device 10 may be stored on storage circuitry 16 (e.g., storage circuitry 16 may include non-transitory (tangible) computer readable storage media that stores the software code). The software code may sometimes be referred to as program instructions, software, data, instructions, or code. Software code stored on storage circuitry 16 may be executed by processing circuitry 18.

Control circuitry 14 may be used to run software on device 10 such as satellite navigation applications, internet browsing applications, voice-over-internet-protocol (VOIP) telephone call applications, email applications, media playback applications, operating system functions, etc. To support interactions with external equipment, control circuitry 14 may be used in implementing communications protocols. Communications protocols that may be implemented using control circuitry 14 include internet protocols, wireless local area network (WLAN) protocols (e.g., IEEE 802.11 protocols-sometimes referred to as Wi-Fi®), protocols for other short-range wireless communications links such as the Bluetooth® protocol or other wireless personal area network (WPAN) protocols, IEEE 802.11ad protocols (e.g., ultra-wideband protocols), cellular telephone protocols (e.g., 3G protocols, 4G (LTE) protocols, 5G New Radio (NR) protocols, etc.), MIMO protocols, antenna diversity protocols, satellite navigation system protocols (e.g., global positioning system (GPS) protocols, global navigation satellite system (GLONASS) protocols, etc.), antenna-based spatial ranging protocols (e.g., radio detection and ranging (RADAR) protocols or other desired range detection protocols for signals conveyed at millimeter and centimeter wave frequencies), or any other desired communications protocols. Each communications protocol may be associated with a corresponding radio access technology (RAT) that specifies the physical connection methodology used in implementing the protocol.

Device 10 may include input-output (IO) circuitry 20. Input-output circuitry 20 may include input-output devices 22. Input-output devices 22 may be used to allow data to be supplied to device 10 and to allow data to be provided from device 10 to external devices. Input-output devices 22 may include user interface devices, data port devices, and other input-output components. For example, input-output devices 22 may include touch sensors, displays, light-emitting components such as displays without touch sensor capabilities, buttons (mechanical, capacitive, optical, etc.), scrolling wheels, touch pads, key pads, keyboards, microphones, cameras, buttons, speakers, status indicators, audio jacks and other audio port components, digital data port devices, motion sensors (accelerometers, gyroscopes, and/or compasses that detect motion), capacitance sensors, proximity sensors, magnetic sensors, force sensors (e.g., force sensors coupled to a display to detect pressure applied to the display), etc. In some configurations, keyboards, headphones, displays, pointing devices such as trackpads, mice, electronic pencil (e.g., a stylus), and joysticks, and other input-output devices may be coupled to device 10 using wired or wireless connections (e.g., some of input-output devices 22 may be peripherals that are coupled to a main processing unit or other portion of device 10 via a wired or wireless link).

Input-output circuitry 20 may include wireless communications circuitry such as wireless communications circuitry 24 (sometimes referred to herein as wireless circuitry 24) for wirelessly conveying radio-frequency signals. While control circuitry 14 is shown separately from wireless communications circuitry 24 for the sake of clarity, wireless communications circuitry 24 may include processing circuitry that forms a part of processing circuitry 18 and/or storage circuitry that forms a part of storage circuitry 16 of control circuitry 14 (e.g., portions of control circuitry 14 may be implemented on wireless communications circuitry 24). As an example, control circuitry 14 (e.g., processing circuitry 18) may include baseband processor circuitry or other control components that form a part of wireless communications circuitry 24.

Wireless communications circuitry 24 may include radio-frequency (RF) transceiver circuitry formed from one or more integrated circuits, power amplifier circuitry configured to amplify uplink radio-frequency signals (e.g., radio-frequency signals transmitted by device 10 to an external device), low-noise amplifiers configured to amplify downlink radio-frequency signals (e.g., radio-frequency signals received by device 10 from an external device), passive radio-frequency components, one or more antennas, transmission lines, and other circuitry for handling radio-frequency wireless signals. Wireless signals can also be sent using light (e.g., using infrared communications).

Wireless circuitry 24 may include radio-frequency transceiver circuitry for handling transmission and/or reception of radio-frequency signals in various radio-frequency communications bands. For example, the radio-frequency transceiver circuitry may handle wireless local area network (WLAN) communications bands such as the 2.4 GHz and 5 GHz Wi-Fi® (IEEE 802.11) bands, wireless personal area network (WPAN) communications bands such as the 2.4 GHZ Bluetooth® communications band, cellular telephone communications bands such as a cellular low band (LB) (e.g., 600 to 960 MHZ), a cellular low-midband (LMB) (e.g., 1400 to 1550 MHZ), a cellular midband (MB) (e.g., from 1700 to 2200 MHZ), a cellular high band (HB) (e.g., from 2300 to 2700 MHZ), a cellular ultra-high band (UHB) (e.g., from 3300 to 5000 MHZ), or other cellular communications bands between about 600 MHZ and about 5000 MHz (e.g., 3G bands, 4G LTE bands, 5G New Radio Frequency Range 1 (FR1) bands below 10 GHz, 5G New Radio Frequency Range 2 (FR2) bands at millimeter and centimeter wavelengths between 20 and 60 GHZ, etc.), a near-field communications (NFC) band (e.g., at 13.56 MHZ), satellite navigations bands (e.g., an L1 global positioning system (GPS) band at 1575 MHZ, an L5 GPS band at 1176 MHz, a Global Navigation Satellite System (GLONASS) band, a BeiDou Navigation Satellite System (BDS) band, etc.), an ultra-wideband (UWB) communications band supported by the IEEE 802.15.4 protocol and/or other UWB communications protocols (e.g., a first UWB communications band at 6.5 GHZ and/or a second UWB communications band at 8.0 GHz), and/or any other desired communications bands. The communications bands handled by such radio-frequency transceiver circuitry may sometimes be referred to herein as frequency bands or simply as “bands,” and may span corresponding ranges of frequencies. In general, the radio-frequency transceiver circuitry within wireless circuitry 24 may cover (handle) any desired frequency bands of interest.

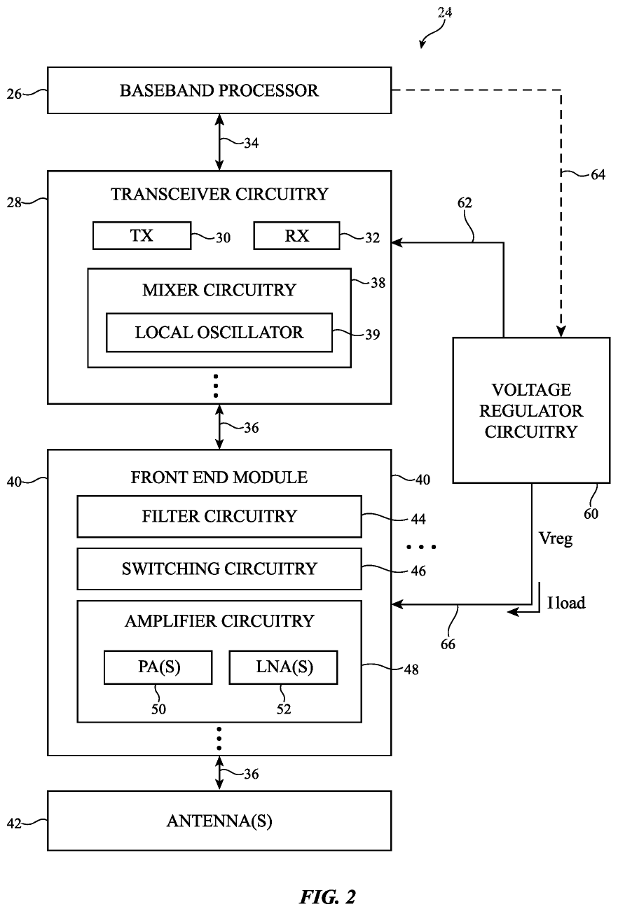

FIG. 2 is a diagram showing illustrative components within wireless circuitry 24. As shown in FIG. 2, wireless circuitry 24 may include a baseband processor such as baseband processor 26, radio-frequency (RF) transceiver circuitry such as radio-frequency transceiver 28, radio-frequency front end circuitry such as radio-frequency front end module (FEM) 40, and antenna(s) 42. Baseband processor 26 may be coupled to transceiver 28 over baseband path 34. Transceiver 28 may be coupled to antenna 42 via radio-frequency transmission line path 36. Radio-frequency front end module 40 may be disposed along the radio-frequency transmission line path 36 between transceiver 28 and antenna 42.

In the example of FIG. 2, wireless circuitry 24 is illustrated as including only a single baseband processor 26, a single transceiver 28, a single front end module 40, and a single antenna 42 for the sake of clarity. In general, wireless circuitry 24 may include any desired number of baseband processors 26, any desired number of transceivers 28, any desired number of front end modules 40, and any desired number of antennas 42. Each baseband processor 26 may be coupled to one or more transceiver 28 over respective baseband paths 34. Each transceiver 28 may include a transmitter circuit 30 (e.g., a digital transmitter and an analog transmitter) configured to output uplink signals to antenna 42, may include a receiver circuit 32 configured to receive downlink signals from antenna 42, and may be coupled to one or more antennas 42 over respective radio-frequency transmission line paths 36. Each radio-frequency transmission line path 36 may have a respective front end module 40 disposed thereon. If desired, two or more front end modules 40 may be disposed along the same radio-frequency transmission line path 36. If desired, one or more of the radio-frequency transmission line paths 36 in wireless circuitry 24 may be implemented without any front end module.

Radio-frequency transmission line path 36 may be coupled to an antenna feed on antenna 42. The antenna feed may, for example, include a positive antenna feed terminal and a ground antenna feed terminal. Radio-frequency transmission line path 36 may have a positive transmission line signal path such that is coupled to the positive antenna feed terminal on antenna 42. Radio-frequency transmission line path 36 may have a ground transmission line signal path that is coupled to the ground antenna feed terminal on antenna 42. This example is merely illustrative and, in general, antennas 42 may be fed using any desired antenna feeding scheme. If desired, antenna 42 may have multiple antenna feeds that are coupled to one or more radio-frequency transmission line paths 36.

Radio-frequency transmission line path 36 may include transmission lines that are used to route radio-frequency antenna signals within device 10 (FIG. 1). Transmission lines in device 10 may include coaxial cables, microstrip transmission lines, stripline transmission lines, edge-coupled microstrip transmission lines, edge-coupled stripline transmission lines, transmission lines formed from combinations of transmission lines of these types, etc. Transmission lines in device 10 such as transmission lines in radio-frequency transmission line path 36 may be integrated into rigid and/or flexible printed circuit boards. In one suitable arrangement, radio-frequency transmission line paths such as radio-frequency transmission line path 36 may also include transmission line conductors integrated within multilayer laminated structures (e.g., layers of a conductive material such as copper and a dielectric material such as a resin that are laminated together without intervening adhesive). The multilayer laminated structures may, if desired, be folded or bent in multiple dimensions (e.g., two or three dimensions) and may maintain a bent or folded shape after bending (e.g., the multilayer laminated structures may be folded into a particular three-dimensional shape to route around other device components and may be rigid enough to hold its shape after folding without being held in place by stiffeners or other structures). All of the multiple layers of the laminated structures may be batch laminated together (e.g., in a single pressing process) without adhesive (e.g., as opposed to performing multiple pressing processes to laminate multiple layers together with adhesive).

In performing wireless transmission, baseband processor 26 may provide baseband signals to transceiver 28 over baseband path 34. Transceiver 28 may further include circuitry for converting the baseband signals received from baseband processor 26 into corresponding radio-frequency signals. For example, transceiver circuitry 28 may include mixer circuitry 38 for up-converting (or modulating) the baseband signals output from the digital transmitter portion of transmitter 30 to radio-frequencies prior to transmission over antenna 42. Mixer circuitry 38 can include oscillator circuitry such as a local oscillator 39. Local oscillator 39 can generate oscillator signals that mixer circuitry 38 uses to modulate transmitting signals from baseband frequencies to radio frequencies. Transceiver circuitry 28 may also include digital-to-analog converter (DAC) and/or analog-to-digital converter (ADC) circuitry for converting signals between digital and analog domains. Transceiver 28 may include a transmitter component to transmit the radio-frequency signals over antenna 42 via radio-frequency transmission line path 36 and front end module 40. Antenna 42 may transmit the radio-frequency signals to external wireless equipment by radiating the radio-frequency signals into free space.

In performing wireless reception, antenna 42 may receive radio-frequency signals from the external wireless equipment. The received radio-frequency signals may be conveyed to transceiver 28 via radio-frequency transmission line path 36 and front end module 40. Transceiver 28 may include circuitry for converting the received radio-frequency signals into corresponding baseband signals. For example, transceiver 28 may use mixer circuitry 38 for down-converting (or demodulating) the received radio-frequency signals to baseband frequencies prior to conveying the received signals to baseband processor 26 over baseband path 34. Local oscillator 39 can generate oscillating signals that mixer circuitry 38 uses to demodulate the received signals from radio frequencies to baseband frequencies.

Front end module (FEM) 40 may include radio-frequency front end circuitry that operates on the radio-frequency signals conveyed (transmitted and/or received) over radio-frequency transmission line path 36. FEM 40 may, for example, include front end module (FEM) components such as radio-frequency filter circuitry 44 (e.g., low pass filters, high pass filters, notch filters, band pass filters, multiplexing circuitry, duplexer circuitry, diplexer circuitry, triplexer circuitry, etc.), switching circuitry 46 (e.g., one or more radio-frequency switches), radio-frequency amplifier circuitry 48 (e.g., one or more power amplifier circuits 50 and/or one or more low-noise amplifier circuits 52), impedance matching circuitry (e.g., circuitry that helps to match the impedance of antenna 42 to the impedance of radio-frequency transmission line 36), antenna tuning circuitry (e.g., networks of capacitors, resistors, inductors, and/or switches that adjust the frequency response of antenna 42), radio-frequency coupler circuitry, charge pump circuitry, power management circuitry, digital control and interface circuitry, and/or any other desired circuitry that operates on the radio-frequency signals transmitted and/or received by antenna 42. Each of the front end module components may be mounted to a common (shared) substrate such as a rigid printed circuit board substrate or flexible printed circuit substrate. If desired, the various front end module components may also be integrated into a single integrated circuit chip.

Filter circuitry 44, switching circuitry 46, amplifier circuitry 48, and other circuitry may be positioned along radio-frequency transmission line path 36, may be incorporated into FEM 40, and/or may be incorporated into antenna 42 (e.g., to support antenna tuning, to support operation in desired frequency bands, etc.). These components, sometimes referred to herein as antenna tuning components, may be adjusted (e.g., using control circuitry 14) to adjust the frequency response and wireless performance of antenna 42 over time.

Transceiver 28 may be separate from front end module 40. For example, transceiver 28 may be formed on another substrate such as the main logic board of device 10, a rigid printed circuit board, or flexible printed circuit that is not a part of front end module 40. While control circuitry 14 is shown separately from wireless circuitry 24 in the example of FIG. 1 for the sake of clarity, wireless circuitry 24 may include processing circuitry that forms a part of processing circuitry 18 and/or storage circuitry that forms a part of storage circuitry 16 of control circuitry 14 (e.g., portions of control circuitry 14 may be implemented on wireless circuitry 24). As an example, baseband processor 26 and/or portions of transceiver 28 (e.g., a host processor on transceiver 28) may form a part of control circuitry 14. Control circuitry 14 (e.g., portions of control circuitry 14 formed on baseband processor 26, portions of control circuitry 14 formed on transceiver 28, and/or portions of control circuitry 14 that are separate from wireless circuitry 24) may provide control signals (e.g., over one or more control paths in device 10) that control the operation of front end module 40.

Transceiver circuitry 28 may include wireless local area network transceiver circuitry that handles WLAN communications bands (e.g., Wi-Fi® (IEEE 802.11) or other WLAN communications bands) such as a 2.4 GHZ WLAN band (e.g., from 2400 to 2480 MHZ), a 5 GHZ WLAN band (e.g., from 5180 to 5825 MHZ), a Wi-Fi® 6E band (e.g., from 5925-7125 MHZ), and/or other Wi-Fi® bands (e.g., from 1875-5160 MHZ), wireless personal area network transceiver circuitry that handles the 2.4 GHz Bluetooth® band or other WPAN communications bands, cellular telephone transceiver circuitry that handles cellular telephone bands (e.g., bands from about 600 MHz to about 5 GHZ, 3G bands, 4G LTE bands, 5G New Radio Frequency Range 1 (FR1) bands below 10 GHz, 5G New Radio Frequency Range 2 (FR2) bands between 20 and 60 GHz, etc.), near-field communications (NFC) transceiver circuitry that handles near-field communications bands (e.g., at 13.56 MHz), satellite navigation receiver circuitry that handles satellite navigation bands (e.g., a GPS band from 1565 to 1610 MHZ, a Global Navigation Satellite System (GLONASS) band, a BeiDou Navigation Satellite System (BDS) band, etc.), ultra-wideband (UWB) transceiver circuitry that handles communications using the IEEE 802.15.4 protocol and/or other ultra-wideband communications protocols, and/or any other desired radio-frequency transceiver circuitry for covering any other desired communications bands of interest.

Wireless circuitry 24 may include one or more antennas such as antenna 42. Antenna 42 may be formed using any desired antenna structures. For example, antenna 42 may be an antenna with a resonating element that is formed from loop antenna structures, patch antenna structures, inverted-F antenna structures, slot antenna structures, planar inverted-F antenna structures, helical antenna structures, monopole antennas, dipoles, hybrids of these designs, etc. Two or more antennas 42 may be arranged into one or more phased antenna arrays (e.g., for conveying radio-frequency signals at millimeter wave frequencies). Parasitic elements may be included in antenna 42 to adjust antenna performance. Antenna 42 may be provided with a conductive cavity that backs the antenna resonating element of antenna 42 (e.g., antenna 42 may be a cavity-backed antenna such as a cavity-backed slot antenna).

In accordance with some embodiments, one or more components within wireless circuitry 24 can be regulated by a voltage regulator such as voltage regulator circuitry 60. As shown in FIG. 2, voltage regulator circuitry 60 can be configured to provide a regulated voltage Vreg to one or more components within front end module 40 over path 66. As an example, voltage regulator circuitry 60 may output a regulated voltage Vreg to a radio-frequency power amplifier 50. As another example, voltage regulator circuitry 60 may provide voltage signal Vreg to a low noise amplifier 52. As another example, voltage regulator circuitry 60 may provide voltage signal Vreg to switching circuitry 46. As another example, voltage regulator circuitry 60 may provide voltage signal Vreg to filter circuitry 44. Voltage regulator circuitry 60 can also be configured to provide regulated voltage Vreg to one or more components within transceiver 28 over path 62. As another example, voltage regulator circuitry 60 can be configured to provide voltage Vreg to radio-frequency digital-to-analog converter (RFDAC), a switched capacitor based circuit, and/or other transceiver component(s). Voltage regulator circuitry 60 can optionally generate Vreg based on digital signals and/or control signals received from baseband processor 26 via path 64.

In general, voltage regulator circuitry 60 can provide regulated voltage Vreg to other components within front end module 40, to one or more components within transceiver circuitry 28, to one or more components within baseband processor 26, to one or more components within antenna circuitry 42, to some other component within wireless circuitry 24, and/or to other components within electronic device 10. Voltage regulator circuitry 60 may, for example, be implemented as a low dropout regulator (LDO). Circuitry 60 can therefore sometimes be referred to as LDO circuitry. To achieve power savings, voltage regulator circuitry 60 may be operated in a high voltage mode and a low voltage mode. When operated in the high voltage mode, voltage regulator circuitry 60 uses a low supply voltage provided on a low voltage rail to output a low voltage at an output port of circuitry 60 (e.g., by driving Vreg to the low supply voltage level). When operated in the high voltage mode, voltage regulator circuitry 60 uses a high supply voltage provided on a high voltage rail to output a high voltage at the output port of circuitry 60 (e.g., by driving Vreg to the high supply voltage level). The high voltage mode is therefore sometimes referred to as a high voltage rail mode/operation, whereas the low voltage mode can be referred to as a low voltage rail mode/operation.

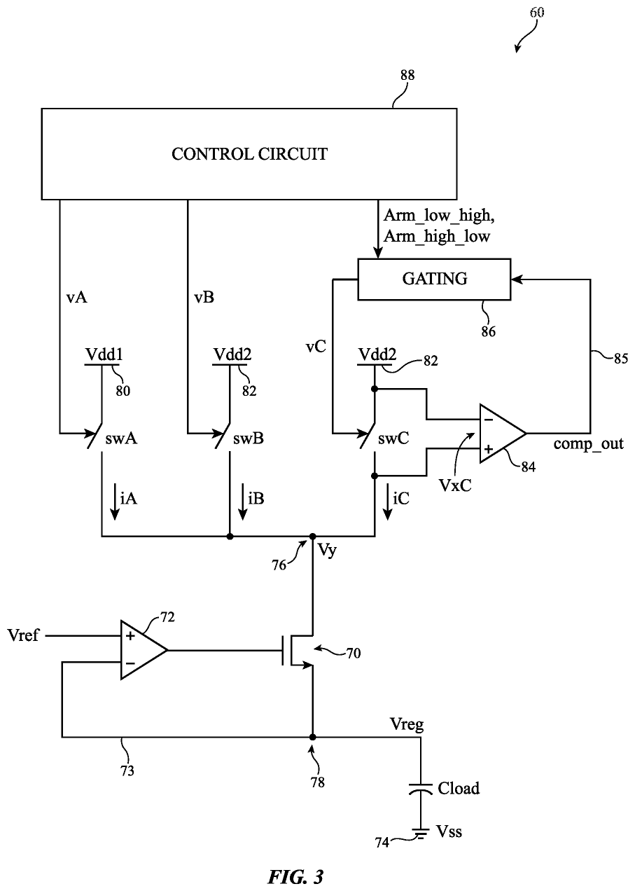

FIG. 3 is a circuit diagram of illustrative voltage regulator circuitry 60. As shown in FIG. 3, voltage regulator circuitry 60 can include a main switch such as main switch 70, an amplifier circuit such as error amplifier 72, a comparator circuit such as comparator 84, voltage rail switches such as switches swA, swB, and swC, a gating circuit such as gating logic 86, and an associated controller such as control circuit 88. Main switch 70 may be implemented as an n-type pass transistor 70 (e.g., a n-channel metal-oxide-semiconductor or NMOS device). Main switch 70 is therefore sometimes referred to as a main transistor, a pass transistor, or an output transistor. Pass transistor 70 may have a drain terminal coupled to node 76, a source terminal coupled to an output port 78 of voltage regulator circuitry 60, and a gate terminal. The terms “source” and “drain” terminals used to refer to current-conveying terminals of a transistor may be used interchangeably and are sometimes referred to as “source-drain” terminals. Thus, transistor 70 can therefore be said to have a first source-drain terminal coupled to node 76 and a second source-drain terminal coupled to output port 78, or vice versa. Node 76 may have a voltage Vy.

The error amplifier 72 can have an output coupled to the gate terminal of pass transistor 70, a first (positive) input configured to receive a reference voltage Vref, and a second (negative) input coupled to output port 78 via a feedback path 73. Arranged in this way, error amplifier 72 outputs a control signal to pass transistor 70. Reference voltage Vref may be a fixed (static) voltage or can be adjusted. Regulated voltage Vreg may be generated at outport port 78, sometimes referred to as a regulator output port. Regulated voltage Vreg, sometimes referred to as a regulator output voltage, can be provided to any load circuit within wireless circuitry 24, as represented by capacitive load Cload being shunted to ground power supply line 74 (e.g., a ground line on which ground power supply voltage Vss is provided).

The voltage rail switches swA, swB, and swC can be coupled to node 76. Switch swA may be coupled between a first voltage rail 80 (e.g., a first power supply line on which first positive power supply voltage Vdd1 is provided) and node 76. Activating switch swA will cause current iA to flow into node 76, and voltage Vy on node 76 will be driven towards Vdd1. Switch swB may be coupled between a second voltage rail 82 (e.g., a second power supply line on which second positive power supply voltage Vdd2 is provided) and node 76. Activating switch swB will cause current iB to flow into node 76, and voltage Vy on node 76 will be driven towards Vdd2. Switch swC may be coupled between the second voltage rail 82 and node 76. Activating switch swC will cause current iC to flow into node 76, and voltage Vy on node 76 will be driven towards Vdd2.

Voltage Vdd1 may be greater than voltage Vdd2. Voltage Vdd1 may be at least 10% greater than Vdd2, 5-15% greater than Vdd2, at least 20% greater than Vdd2, at least 30% greater than Vdd2. 10-50% greater than Vdd2, 50-100% greater than Vdd2, or more than double Vdd2. Voltage Vdd1 is therefore sometimes referred to as a high supply voltage (Vhi), whereas voltage Vdd2 is sometimes referred to as a low supply voltage (Vlo). The first voltage rail 80 is therefore sometimes referred to as a high voltage rail or supply line, whereas second voltage rail 82 may is sometimes referred to as a low voltage rail or supply line. Switch swA connected to the high voltage rail 80 is therefore sometimes referred to and defined herein as a “high rail switch.” Switches swB and swC that are connected to the low voltage rail 82 are therefore sometimes referred to and defined herein as “low rail switches.” The three voltage rail switches swA, swB, and swC can be implemented as p-type transistors (e.g., p-channel metal-oxide-semiconductor or PMOS devices) and/or n-type transistors (e.g., NMOS devices).

The low rail switches swB and swC should be different in sizing. In particular, low rail switch swB can be larger than low rail switch swC. For example, low rail switch swB can be at least two times larger than switch swC, at least three times larger than switch swC, at least four times larger than switch swC, two to five times larger than switch swC, five to ten times larger than switch swC, or more than ten times larger than switch swC. Switch swB can therefore sometimes be referred to and defined herein as the “large/big low rail switch,” whereas switch swC can sometimes be referred to and defined herein as the “small low rail switch.”

The comparator 84 may be coupled across the two terminals of the small low rail switch swC. For example, comparator 84 may have a first (negative) input coupled to a first source-drain terminal of switch swC (assuming switch swC is implemented as a transistor), a second (positive) input coupled to a second source-drain terminal of switch swC, and an output coupled on which a comparator output signal comp_out is generated. Voltage VxC may represent the differential voltage across the two inputs of comparator 84. Gating logic circuit 86 may have an input configured to receive signal comp_out from comparator 84 via path 85, another input configured to receive arming signals from control circuit 88, and an output on which control signal vC is generated. Gating logic circuit 86 may be configured to assert signal vC to turn on (activate) switch swC or deassert signal vC to turn off (deactivate) switch swC based on signals comp_out and based on the arming signals Arm_low_high or Arm_high_low from control circuit 88. The term “activate” with respect to a switch (or transistor) may refer to or be defined herein as an action that places the switch in a low-impedance or on state such that the two terminals of the switch are electrically connected to conduct current. The term “deactivate” with respect to a switch (or transistor) may refer to or be defined herein as an action that places the switch in a high-impedance or off state such that the two terminals of the switch/transistor are electrically disconnected with minimal leakage current.

Control circuit 88 may also be configured to output control signal vA for controlling switch swA and to output control signal vB for controlling switch swB. In particular, control circuit 88 can assert control signal vA to turn on swA or deassert signal vA to turn off swA. Similarly, control circuit 88 can assert signal control signal vB to turn on swB or deassert signal vB to turn off swB. Configured in this way, control circuit 88 may serve as a sequencer or state machine that sets the states of switches swA and swB while selectively gating the output of comparator 84 using gating logic 86 through the use of the arming signals. The loop that includes comparator 84, path 85, gating logic 86, and small low rail switch swC forms a fast analog feedback loop that selectively activates and deactivates switch swC.

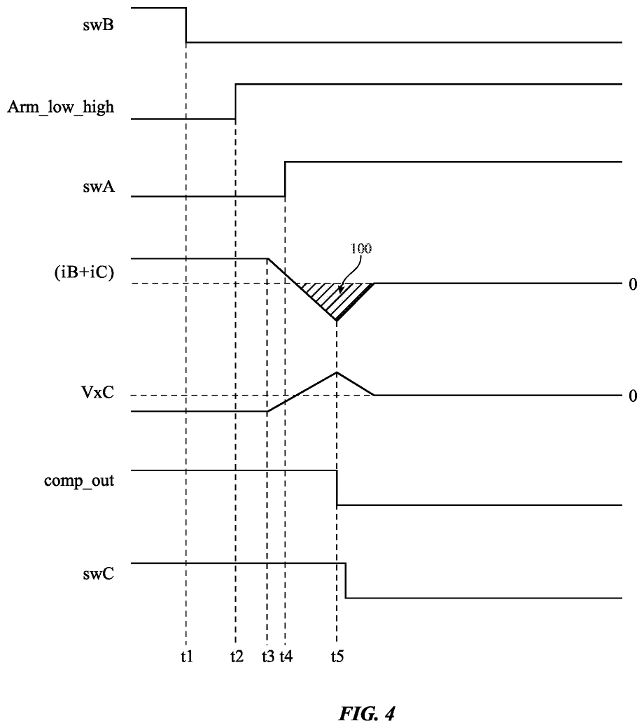

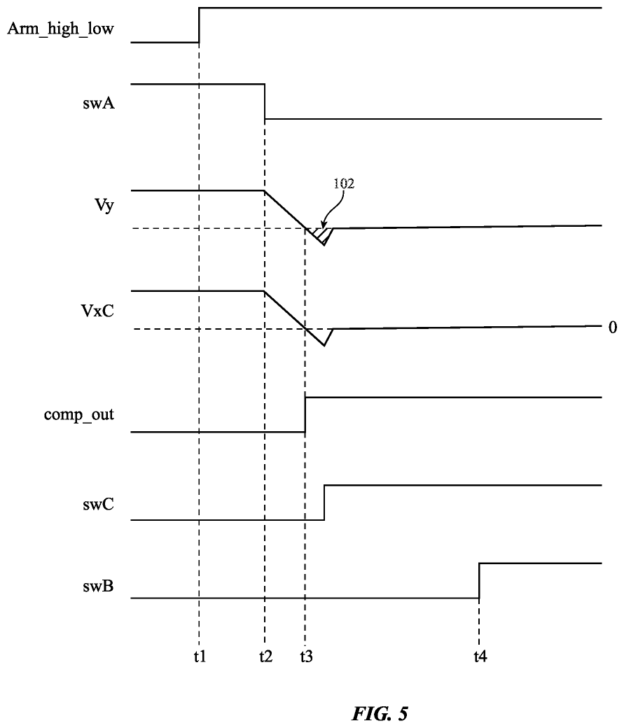

The operation of voltage regulator circuitry 60 of FIG. 3 is best understood by referring to the timing diagrams of FIGS. 4 and 5. As described above, voltage regulator circuitry 60 may be operable in a high voltage rail mode and a low voltage rail mode. During the high voltage rail mode, the higher supply voltage Vdd1 is used to drive the regulator output voltage Vreg. During the low voltage rail mode, the lower supply voltage Vdd2 is used to drive the regulator output voltage Vreg. A fast seamless switching between these two modes without incurring large current glitches may be desirable.

FIG. 4 is a timing diagram illustrating a transition from the low voltage rail mode to the high voltage rail mode. In the steady state of the low voltage rail mode, both of the low rail switches swB and swC can be turned on (activated). At time t1, the large low rail switch swB can be turned off (deactivated). At time t2, control circuit 88 may assert arming signal Arm_low_high, which activates gating logic 86. Activating gating logic 86 enables comparator 84 to monitor the current iC flowing through the small low rail switch swC.

At time t3, control circuit 88 activates the high rail switch swA. Turning on the high rail switch swA can create a cross current flowing through the low rail switches. As shown in FIG. 4, this cross current can result in the low rail current (e.g., a current represented by the sum of current iB flowing through swB and current iC flowing through swC) reversing direction, as indicated by shaded region 100. Comparator 84 can be used to detect such cross current in the low rail switches by monitoring the voltage VxC across the small low rail switch swC. Voltage VxC is the differential voltage at the input of comparator 84. As shown in FIG. 4, the cross current can cause VxC to flip polarities (e.g., from a negative voltage to a positive voltage). When voltage VxC exceeds a positive threshold at time t5, the comparator output signal comp_out can flip or toggle. In the example of FIG. 3, the comparator output signal comp_out can toggle from a high voltage level to a low voltage level or vice versa. When this occurs, gating logic 86—which is already armed—can deassert control signal vC to subsequently turn off the small low rail switch swC.

Performing a low rail to high rail mode transition in this way can be technically advantageous and beneficial by limiting the transient cross (reverse) currents through the low rail switches during the transition while providing fast rail transitions with minimal supply drop and avoiding excessive in-rush current. For example, the transition from the high voltage rail mode to the low voltage rail mode can be completed within 1000 nanoseconds (ns), within 500 ns, within 100-500 ns, or within 100 ns or less.

FIG. 5 is a timing diagram illustrating a transition from the high voltage rail mode to the low voltage rail mode. In the steady state of the high voltage rail mode, only the high rail switch swA is turned on while the low rail switches swB and swC are both deactivated. At time t1, arming signal Arm_high_low can be asserted by control circuit 88. Asserting signal Arm_high_low effectively enables comparator 84. At time t2, control circuit 88 turns off the high rail switch swA (e.g., by deasserting control signal vA). At this point, none of the rail switches are activated (e.g., all three of the voltage rail switches swA, swB, and swC are turned off).

Without any of the rail switches turned on, the voltage Vy at node 76 will begin to drop as current flows into pass transistor 70. This will cause a corresponding drop in voltage VxC at the input of comparator 84. When VxC crosses the comparator threshold on the way down (e.g., when voltage VxC drops below 0 V at time t3), the comparator output signal comp_out can be asserted. Shaded region 102 illustrates an unwanted voltage drop that can be detected by comparator 84. For instance, the comparator output signal comp_out can toggle from a low voltage level to a high voltage level or vice versa. When this occurs, gating logic 86—which is already armed—can assert control signal vC to subsequently turn on the small low rail switch swC. Sometime later at time t4, the big low rail switch swB can then be turned on.

Performing a high rail to low rail mode transition in this way can be technically advantageous and beneficial by limiting the transient cross (reverse) currents through the low rail switches during the transition while providing fast rail transitions with minimal supply drop and avoiding excessive in-rush current. For example, the transition from the low voltage rail mode to the high voltage rail mode can be completed within 1000 nanoseconds (ns), within 500 ns, within 100-500 ns, or within 100 ns or less.

The threshold level at which comparator toggles during the low to high rail transition and during the high to low rail transition can be different. In the example of FIG. 4, comparator 84 toggles when the differential input voltage VxC exceeds a positive threshold level. In the example of FIG. 5, comparator 84 toggles when the differential input voltage VxC falls below a neutral threshold level of 0 V. This is exemplary. In general, the comparator threshold for the low to high rail transition can be different than the comparator threshold for the high to low rail transition. This feature in which the comparator threshold changes depending on the directionality of the transition can be implemented using comparator 84 with hysteresis.

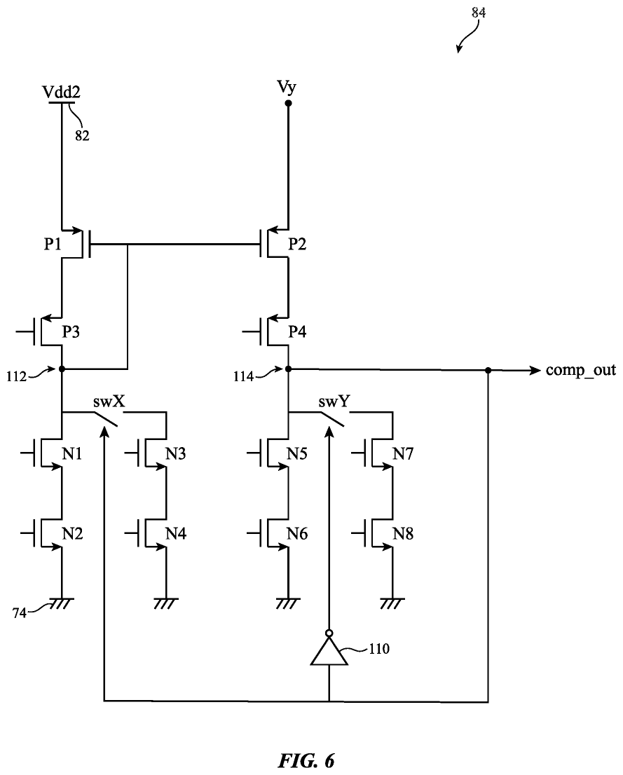

FIG. 6 is a circuit diagram of an illustrative comparator 84 with hysteresis in accordance with some embodiments. As shown in FIG. 6, comparator 84 may include p-type transistors P1, P2, P3, and P4 (e.g., PMOS transistors), n-type transistors N1, N2, N3, N4, N5, N6, N7, and N8, comparator switches swX and swY, and an inverter 110. Transistor P1 may have a source terminal (e.g., the positive input of comparator 84) coupled to the Vdd2 power supply line 82, a gate terminal coupled to node 112, and a drain terminal coupled to transistor P3. Transistor P3 may have a source terminal coupled to transistor P1 and a drain terminal coupled to node 112. Transistors N1 and N3 may be coupled in series between node 112 and ground line 74. Transistors N3 and N4 may be coupled in series and selectively coupled to node 112 via switch swX. Comparator switch swX may be controlled by the comparator output signal comp_out.

Transistor P2 may have a source terminal (e.g., the negative input of comparator 84) configured to receive voltage Vy, a gate terminal coupled to the gate terminal of transistor P1, and a drain terminal coupled to transistor P4. Transistor P4 may have a source terminal coupled to transistor P2 and a drain terminal coupled to comparator output port 114 (e.g., an output port on which comparator output signal comp_out is generated). Transistors N5 and N6 may be coupled in series between node 114 and the ground line. Transistors N7 and N8 may be coupled in series and selectively coupled to node 114 via switch swY. Comparator switch swY may be controlled by an inverted version of the comparator output signal comp_out output from inverter 110. Configured in this way, comparator switches swX and swY control the hysteresis. When signal comp_out is low, switch swX is turned off while switch swY is turned on. Conversely, when signal comp_out is high, switch swX is turned on while switch swY is turned off.

The comparator architecture of FIG. 6 is exemplary and not intended to limit the scope of the present embodiments. If desired, other types of comparator topology that exhibit hysteresis can be employed.

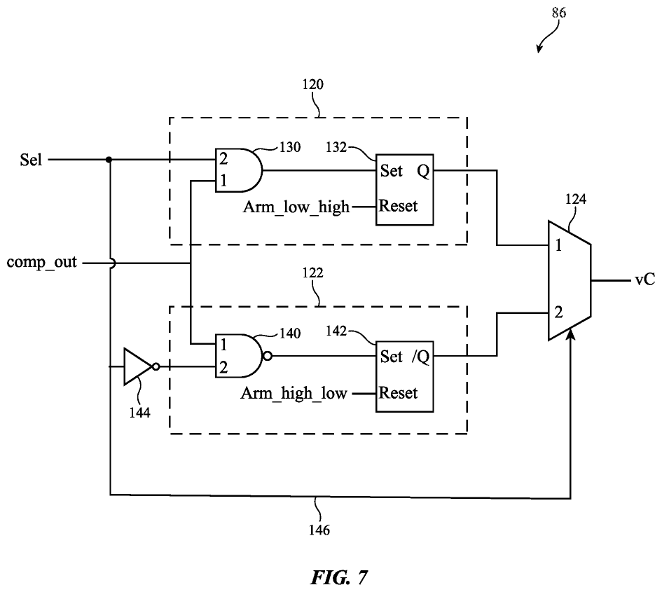

FIG. 7 is a circuit diagram of illustrative gating logic circuit 86 in accordance with some embodiments. As shown in FIG. 7, gate logic circuit 86 may include latches 132 and 142, logic gates 130, 140, and 144, and a multiplexer 124. Logic gate 130 may be a logic AND gate having a first (1) input configured to receive the comparator output signal comp_out, a second (2) input configured to receive a select signal Sel, and an output coupled to latch 132. Latch 132 may be implemented as a set-reset latch (as an example) having a set input coupled to the output of logic AND gate 130, a reset input configured to receive arming signal Arm_low_high, and an output Q. Logic gate 130 and latch 132 may collectively serve as a low-to-high rail transition logic path 120.

Logic gate 140 may be a logic NAND gate having a first (1) input configured to receive the comparator output signal comp_out, a second (2) input configured to receive an inverted version of select signal Sel via inverter 144, and an output coupled to latch 142. Latch 142 may be implemented as a set-reset latch (as an example) having a set input coupled to the output of logic NAND gate 140, a reset input configured to receive arming signal Arm_high_low, and an output/Q. An inverted version of the latched input signal can be presented at output/Q. Logic gate 140 and latch 142 may collectively serve as a high-to-low rail transition logic path 122. Multiplexer 124 may have a first input coupled to the output of latch 132, a second input coupled to the output of latch 142, a control input configured to receive select signal Sel, and an output on which signal vC for controlling the small low rail switch swC is generated. Gating logic 86 of FIG. 7 is illustrative and not intended to limit the scope of the present embodiments. If desired, other ways of implementing gating logic 86 for selectively activating the small low rail switch swC based on the comparator output signal and the arming signals Arm_low_high and Arm_high_low can be employed. If desired, other types of latches or flip-flops can be used in the two logic paths 120 and 122.

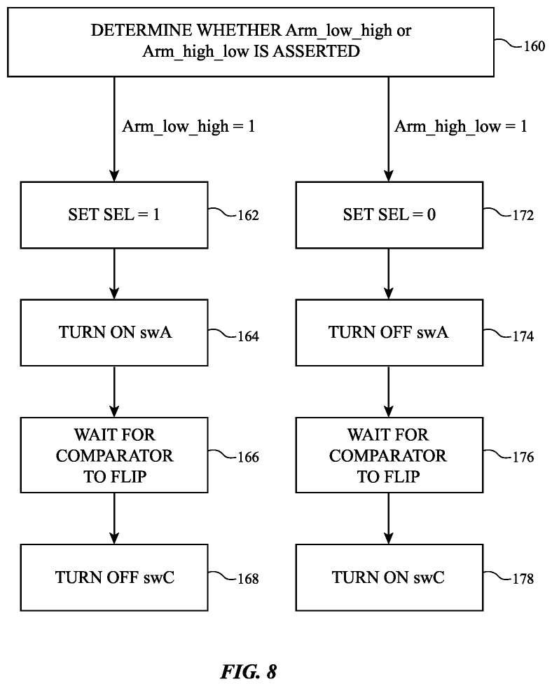

FIG. 8 is a flow chart of illustrative steps for operating voltage regulator circuitry 60 of the type shown in FIGS. 2-7. During the operations of block 160, gating logic 86 may check whether Arm_low_high or Arm_high_low is asserted. If arming signal Arm_low_high is asserted or driven high by control circuit 88, then control circuit 88 is initiating a transition from the low voltage rail mode to the high voltage rail mode. In response, the select signal Sel can be asserted (e.g., set equal to logic one) during the operations of block 162. During the operations of block 164, the high rail switch swA can be activated (e.g., by asserting control signal vA). During the operations of block 166, the analog feedback loop in which comparator 84 is disposed may wait for comparator 84 to flip. When comparator 84 flips or toggles (see, e.g., FIG. 4 when the comparator differential input voltage VxC exceeds a first threshold level), gating logic 86 may deactivate the small low rail switch swC by deasserting control signal vC.

If arming signal Arm_high_low is asserted or driven high by control circuit 88, then control circuit 88 is initiating a transition from the high voltage rail mode to the low voltage rail mode. In response, the select signal Sel can be deasserted (e.g., set equal to logic zero) during the operations of block 172. During the operations of block 174, the high rail switch swA can be deactivated (e.g., by deasserting control signal vA). During the operations of block 176, the analog feedback loop in which comparator 84 is disposed may wait for comparator 84 to flip. When comparator 84 flips or toggles (see, e.g., FIG. 5 when the comparator differential input voltage VxC falls below a second threshold level different than the first threshold level due to hysteresis), gating logic 86 may activate the small low rail switch swC by asserting control signal vC.

The operations of FIG. 8 are merely illustrative. At least some of the described operations may be modified or omitted; some of the described operations may be performed in parallel; additional processes may be added or inserted between the described operations; the order of certain operations may be reversed or altered; the timing of the described operations may be adjusted so that they occur at slightly different times, or the described operations may be distributed in a system.

The methods and operations described above in connection with FIGS. 1-8 may be performed by the components of device 10 using software, firmware, and/or hardware (e.g., dedicated circuitry or hardware). Software code for performing these operations may be stored on non-transitory computer readable storage media (e.g., tangible computer readable storage media) stored on one or more of the components of device 10 (e.g., storage circuitry 16 and/or wireless communications circuitry 24 of FIG. 1). The software code may sometimes be referred to as software, data, instructions, program instructions, or code. The non-transitory computer readable storage media may include drives, non-volatile memory such as non-volatile random-access memory (NVRAM), removable flash drives or other removable media, other types of random-access memory, etc. Software stored on the non-transitory computer readable storage media may be executed by processing circuitry on one or more of the components of device 10 (e.g., processing circuitry in wireless circuitry 24, processing circuitry 18 of FIG. 1, etc.). The processing circuitry may include microprocessors, application processors, digital signal processors, central processing units (CPUs), application-specific integrated circuits with processing circuitry, or other processing circuitry.

The foregoing is merely illustrative and various modifications can be made to the described embodiments. The foregoing embodiments may be implemented individually or in any combination.

What is claimed is:

1. Voltage regulator circuitry comprising:
a pass transistor having a source terminal coupled to an output port of the voltage regulator circuitry on which a regulated voltage is provided;
an amplifier having a first input configured to receive a reference voltage, a second input coupled to the source terminal of the pass transistor, and an output coupled to a gate terminal of the pass transistor;
a first switch coupled between a first power supply line and a drain terminal of the pass transistor; and
a second switch coupled between the first power supply line and the drain terminal of the pass transistor.

2. The voltage regulator circuitry of claim 1, further comprising:
a third switch coupled between a second power supply line different than the first power supply line and the drain terminal of the pass transistor, wherein
a first power supply voltage is provided on the first power supply line,
a second power supply voltage is provided on the second power supply line, and
the first power supply voltage is greater than the second power supply voltage.

3. The voltage regulator circuitry of claim 2, further comprising:
a comparator having input terminals coupled across the first switch and configured to generate a comparator output signal.

4. The voltage regulator circuitry of claim 3, wherein the comparator comprises:
a first comparator switch configured to receive the comparator output signal;
a second comparator switch configured to receive the comparator output signal, wherein the first and second comparator switches are used to implement a hysteresis for the comparator.

5. The voltage regulator circuitry of claim 3, further comprising:
a gating circuit configured to receive the comparator output signal and to output a first control signal for controlling the first switch.

6. The voltage regulator circuitry of claim 5, further comprising:
a control circuit configured to output a first arming signal and a second arming signal to the gating circuit, to output a second control signal for controlling the first switch, and to output a third control signal for controlling the second switch.

7. The voltage regulator circuitry of claim 6, wherein the gating circuit comprises:
a first latch configured to receive the first arming signal from the control circuit; and
a second latch configured to receive the second arming signal from the control circuit.

8. The voltage regulator circuitry of claim 7, wherein the gating circuit further comprises:
a first logic gate having a first input configured to receive the comparator output signal, a second input configured to receive a select signal, and an output coupled to the first latch; and
a second logic gate having a first input configured to receive the comparator output signal, a second input configured to receive an inverted version of the select signal, and an output coupled to the second latch.

9. The voltage regulator circuitry of claim 8, wherein the gating circuit further comprises:
a multiplexer having a first input coupled to the first latch, a second input coupled to the second latch, a control input configured to receive the select signal, and an output coupled to the second switch.

10. The voltage regulator circuitry of claim 1, wherein the second switch is at least two times larger than the first switch.

11. A method of operating voltage regulator circuitry, comprising:
outputting, by an error amplifier, a control signal to a pass transistor;
deactivating a second low rail switch coupled between a first power supply line and the pass transistor;
after deactivating the second low rail switch, activating a high rail switch coupled between a second power supply line different than the first power supply line and the pass transistor; and
receiving, at a comparator, a voltage across a first low rail switch coupled between the first power supply line and the pass transistor.

12. The method of claim 11, further comprising:
after deactivating the second low rail switch and before activating the high rail switch, asserting an arming signal to arm the comparator.

13. The method of claim 11, further comprising:
in response to a voltage across the first low rail switch exceeding a threshold of the comparator, toggling a comparator output signal at an output of the comparator.

14. The method of claim 13, further comprising:
in response to the comparator output signal toggling, deactivating the first low rail switch.

15. The method of claim 11, wherein:
a first power supply voltage is provided on the first power supply line;
a second power supply voltage is provided on the second power supply line;
the second power supply voltage is greater than the first power supply voltage; and
the second low rail switch is larger than the first low rail switch.

16. A method of operating voltage regulator circuitry, comprising:
outputting, by an error amplifier, a control signal to a pass transistor;
deactivating a high rail switch coupled between a first power supply line and the pass transistor;
receiving, at a comparator, a voltage across a first low rail switch coupled between a second power supply line different than the first power supply line and the pass transistor; and
in response to the voltage across the first low rail switch exceeding a threshold of the comparator, toggling a comparator output signal at an output of the comparator.

17. The method of claim 16, further comprising:
before deactivating the high rail switch, asserting an arming signal to arm the comparator.

18. The method of claim 16, further comprising:
in response to the comparator output signal toggling, activating the first low rail switch.

19. The method of claim 18, further comprising:
after activating the first low rail switch, activating a second low rail switch that is coupled between the second power supply line and the pass transistor.

20. The method of claim 16, wherein:
a first power supply voltage is provided on the first power supply line;
a second power supply voltage is provided on the second power supply line;
the first power supply voltage is greater than the second power supply voltage; and
the second low rail switch is larger than the first low rail switch.
